(19) United States
(12) Patent Application Publication
(10) Pub. No.: US 2024/0178261 A1
(43) Pub. Date: May 30, 2024

(54) CHIP PACKAGE AND METHOD FOR FORMING THE SAME

(71) Applicant: XINTEC INC., Taoyuan City (TW)

(72) Inventors: Kuei-Wei CHEN, Taoyuan City (TW); Chao-Yuan YANG, Taoyuan City (TW); Yueh Hsien LI, Hsinchu City (TW)

(21) Appl. No.: 18/491,713

(22) Filed: Oct. 20, 2023

Related U.S. Application Data
(60) Provisional application No. 63/428,717, filed on Nov. 29, 2022.

(51) Int. Cl. H01L 27/146

(52) U.S. Cl. CPC H01L 27/14636; H01L 27/14618; H01L 27/14625; H01L 27/14632; H01L 27/14634; H01L 27/14687; H01L 27/1469

(57) ABSTRACT

Chip packages and methods for forming the same are provided. The chip package includes a substrate having a stepped sidewall, a first surface, and a second surface. The first surface and the second surface are opposite each other. The first surface and the second surface adjoin the stepped sidewall. The chip package also includes a capping layer having a first surface and a second surface opposite each other. The first surface of the capping layer faces the second surface of the substrate. The chip package further includes a dam structure and an adhesive layer. The dam structure bonds the capping layer to the substrate, and surrounds a sensing region in the substrate. The adhesive layer surrounds the dam structure and has a concave-tapered sidewall that extends along the outer edge of the dam structure in the direction from the second surface of the substrate to the capping layer.

### CROSS REFERENCE TO RELATED APPLICATIONS

This application claims the benefit of U.S. Provisional Application No. 63/428,717, filed Nov. 29, 2022, the entirety of which is incorporated by reference herein.

### BACKGROUND OF THE INVENTION

### Field of the Invention

The invention relates to package technology, and in particular to a chip package and a method for forming the same.

### Description of the Related Art

Optoelectronic devices (e.g., image-sensing devices) play an important role in capturing images. They are widely used in electronic products such as digital cameras, digital video recorders, and mobile phones. The chip packaging process is an important step in the fabrication of any electronic product. Chip packages not only protect sensing chips from outside environmental contaminants, but they also provide electrical connection paths between the electronic elements inside and those outside of the chip packages.

With the increasing complexity of chip packaging manufacturing processes, many challenges have arisen. For example, during chip package manufacturing, there are challenges such as the support capability for the cover glass, device defects associated with the singulation process, and the filling capability of the encapsulant layer.

Accordingly, there is a need for novel chip packages and methods for forming the same that are capable of addressing or mitigating the challenges faced during the formation of chip packages.

### BRIEF SUMMARY OF THE INVENTION

An embodiment provides a chip package that includes a substrate having a stepped sidewall and a first surface and a second surface opposite each other and adjoining the stepped sidewall. The chip package also includes a capping layer having a first surface and a second surface opposite each other. The first surface of the capping layer faces the second surface of the substrate. The chip package further includes a dam structure bonding the capping layer to the substrate and surrounding a sensing region in the substrate. In addition, the chip package includes an adhesive layer surrounding the dam structure. The adhesive layer has a concave-tapered sidewall extending along the outer edge of the dam structure in the direction from the second surface of the substrate to the capping layer.

An embodiment provides a chip package that includes a substrate and a capping layer successively stacked on a package substrate. The chip package also includes a dam structure sandwiched between the substrate and the capping layer and surrounding a sensing region in the substrate. The chip package further includes an encapsulant layer formed on the package substrate and surrounding the substrate, the dam structure and the capping layer. In addition, the chip package includes an adhesive layer formed between the lower portion of the dam structure and the encapsulant layer. The bottom width of the substrate is greater than the top width of the substrate. The first interface between the capping layer and the encapsulant layer and the second interface between the encapsulant layer and the upper portion of the dam structure are substantially aligned with each other and extend in the same direction. The encapsulant layer has a rounded angle in direct contact with the adhesive layer.

An embodiment provides a method for forming a chip package that includes: bonding a transparent substrate to a carrier substrate via a tape layer. The transparent substrate has a first region and a second region surrounding the first region. The method also includes forming a dam structure on the transparent substrate. The dam structure extends along the edge of the first region to surround the first region. The method further includes performing a first dicing process to partially remove the dam structure and form an opening in the transparent substrate. The opening surrounds the first region and exposes the tape layer. In addition, the method includes bonding a substrate to the transparent substrate. The substrate has a chip region corresponding to the first region and a scribe-line region corresponding to the second region. The method also includes performing a debonding process to remove the tape layer, the carrier substrate, and a portion of the transparent substrate, so that the remaining transparent substrate forms a capping layer over the substrate and exposes the scribe-line region. The method further includes performing a second dicing process on the exposed scribe-line region, so that the substrate of the chip region forms a stepped sidewall.

### BRIEF DESCRIPTION OF THE FIGS.

The present disclosure can be more fully understood by reading the subsequent detailed description and examples with references made to the accompanying drawings, wherein:

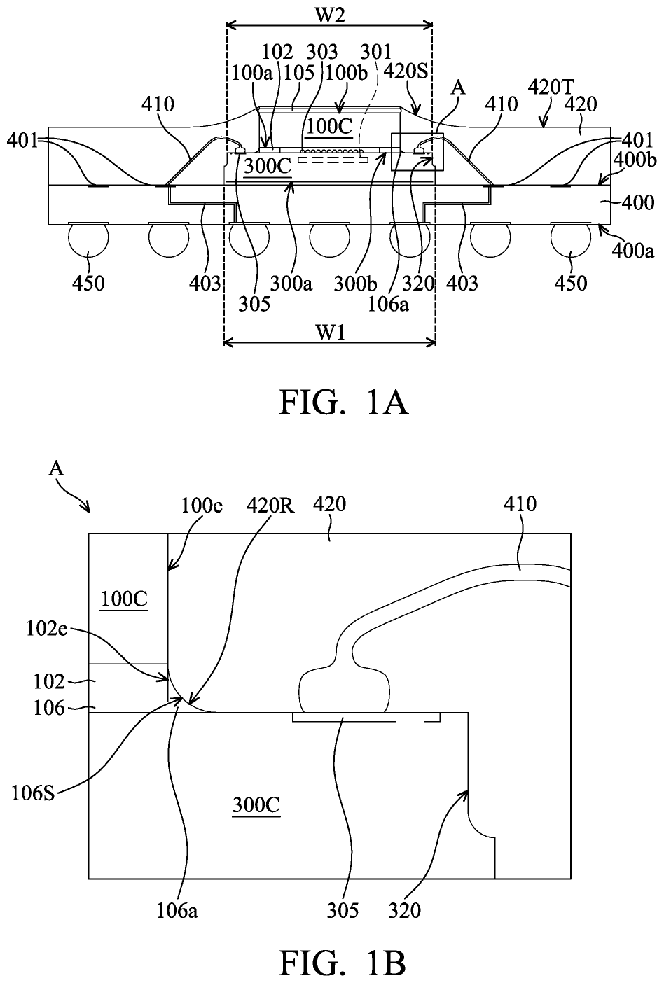

FIG. 1A is a cross-sectional view of an exemplary chip package in accordance with some embodiments.

FIG. 1B is a partially enlarged cross-sectional view of FIG. 1A in accordance with some embodiments.

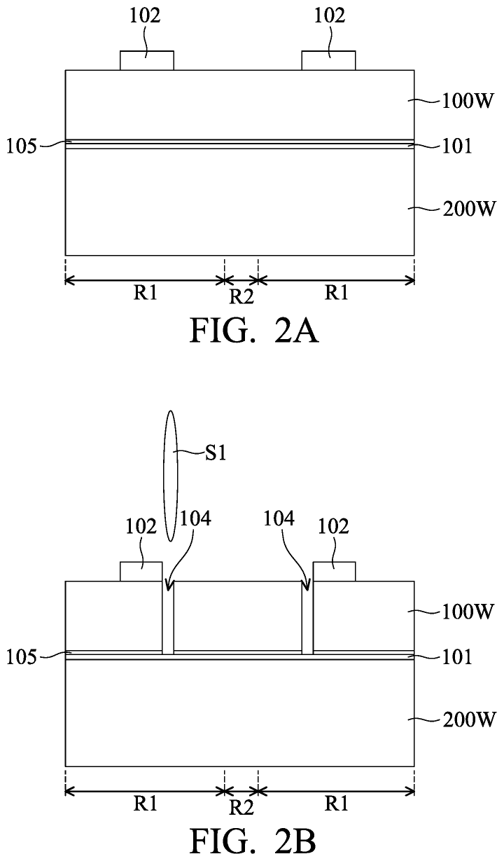

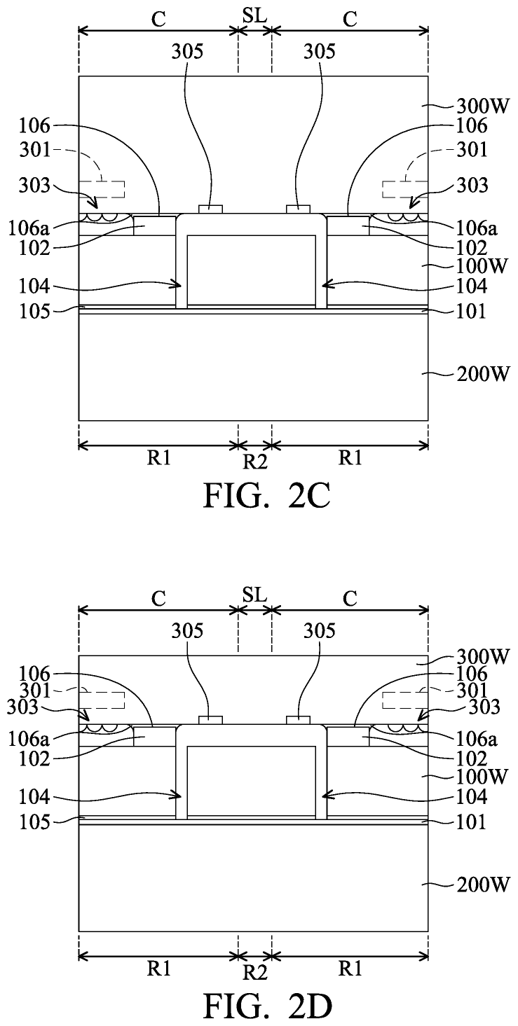

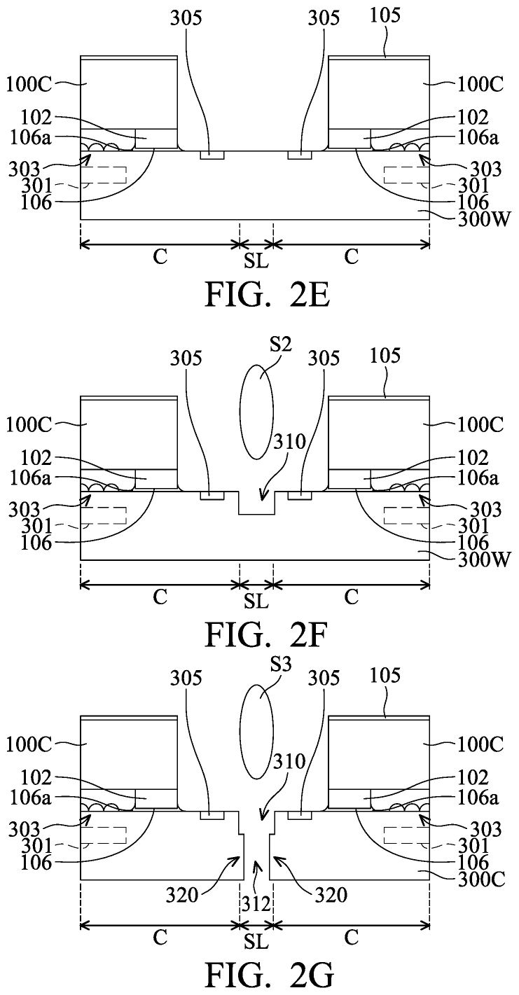

FIGS. 2A to 2G are cross-sectional views of an exemplary method for forming a chip package in accordance with some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Moreover, when a first material layer is referred to as being on or overlying a second material layer, the first material layer may be in direct contact with the second material layer, or separated from the second material layer by one or more material layers.

A chip package according to some embodiments of the present disclosure may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multi-layer integrated circuit devices by a stack of a plurality of wafers having integrated circuits.

Referring to FIGS. 1A and 1B, in which FIG. 1A is a cross-sectional view of an exemplary chip package in accordance with some embodiments, and FIG. 1B is a partially enlarged cross-sectional view of an area A in FIG. 1A in accordance with some embodiments. In some embodiments, the chip package is implemented as a front-side illumination (FSI) sensing device. However, In some other embodiments, the chip package may also be implemented as a backside illumination (BSI) sensing device. For example, the chip package is implemented as a front-side illumination (FSI) sensor and includes a substrate 300C, as shown in FIGS. 1A and 1B. The substrate 300C has a first surface 300a (e.g., the lower surface) and a second surface 300b (e.g., the upper surface) opposite the first surface 300a. Moreover, the substrate 300C has stepped sidewalls 320 that adjoins the first surface 300a and the second surface 300b. The bottom width W1 of the substrate 300C with the stepped sidewalls 320 is greater than its top width W2, as shown in FIG. 1A. Compared to a substrate with vertical sidewalls, the substrate 300C with stepped sidewalls 320 helps to improve the filling or covering ability of the subsequently formed encapsulant layer. In some embodiments, the substrate 300C is a silicon wafer to facilitate the wafer-level packaging process. In some other embodiments, substrate 100 may be a silicon substrate or other semiconductor substrate.

In some embodiments, the substrate 300C includes a sensing region 301. Moreover, the sensing region 301 includes a sensing device (not shown) adjacent to the second surface 300b of the substrate 300C. For example, the sensing region 301 may include an image-sensing device or another suitable sensing device. In other some embodiments, the sensing region 301 includes a device for sensing biometrics (e.g., a fingerprint recognition device), a device for sensing environmental features (e.g., a temperature sensing element, a humidity sensing element, a pressure sensing element, a capacitive sensing element), or another suitable sensing element, a temperature sensing device, a humidity sensing device, a pressure sensing device, a capacitive sensing device), or other suitable sensing devices.

In some embodiments, an insulating layer (not shown) is disposed over substrate 300C, and a surface of the insulating layer forms the second surface 300b of substrate 300C. In some embodiments, the insulating layer includes an interlayer dielectric (ILD) layer, an inter-metal dielectric (IMD) layer, a passivation layer, or a combination thereof. In some embodiments, the insulating layer includes an inorganic material such as silicon oxide, silicon nitride, silicon oxynitride, metal oxide or a combination thereof or another suitable insulating material.

In some embodiments, the insulating layer includes one or more conductive pads 305 therein. The conductive pad 305 may be a single conductive layer or a multi-layer conductive layer structure. To simplify the diagram and description, only the conductive pad 305 with a single conductive layer is depicted as an example. The sensing device in the sensing region of the substrate 300C can be electrically connected to the conductive pad 305 through the interconnect structures (not shown) in the substrate 300C and the insulating layer.

In some embodiments, the chip package further includes an optical component 303. The optical component 303 is disposed on the insulating layer over the second surface 300b of the substrate 300C and corresponds to the sensing region 301. In some embodiments, the optical component 203 includes a microlens array, a filter layer, a combination thereof, or other suitable optical components.

In some embodiments, the chip package further includes a capping layer 100C and an optical film 105. The capping layer 100C is stacked on top of the substrate 300C to cover and protect the optical component 303. In some embodiments, the capping layer 100C may include glass, quartz, a transparent polymer material, or another suitable transparent material.

In some embodiments, the optical film 105 is formed over the first surface 100a the second surface 100b of the capping layer 100C. To simplify the diagram and description, only the optical film 105 is formed over the second surface 100b of the capping layer 100C as an example herein. In some embodiments, the optical film 105 includes an infrared cut filter (IR cut filter), an anti-reflection layer, or a combination thereof. The optical film 105 helps to improve the performance of the sensing device in the sensing region.

In some embodiments, the chip package further includes a dam structure 102 (which is also referred to as a spacer layer) and an adhesive layer 106. The dam structure 102 is employed to bond the capping layer 100C with the substrate 300C. More specifically, the dam structure 102 is sandwiched between the capping layer 100C and the substrate 300C using the adhesive layer 106 and surrounds the sensing region 301 in the substrate 300C. In some embodiments, the outer edge 102e of the dam structure 102 and the edge 100e of the capping layer 100C are substantially aligned with each other and extend in the same direction. That is, the outer edge 102e and the edge 100e form a straight line. As a result, the dam structure 102 formed over the substrate 300C improves the mechanical support of the dam structure 102 to the capping layer 100C overlying the dam structure 102. In some embodiments, the dam structure 102 includes an epoxy resin, an inorganic material (such as silicon oxide, silicon nitride, silicon oxynitride, metal oxide or a combination thereof), an organic polymer material (such as polyimide, butylcyclobutene (BCB), parylene, polynaphthalenes, fluorocarbons or acrylates), or a photoresist material, or another suitable insulating material.

In some embodiments, as shown in FIG. 1B, a portion of the adhesive layer 106 formed between the dam structure 102 and the capping layer 100C overflows and surrounds the lower portion of the dam structure 102 along the outer edge 102e of the dam structure 102. Herein, the overflowing portion of the adhesive layer 106 is also referred to as a glue overflow layer 106a. The formed glue overflow layer 106a has a concave-tapered sidewall 106S extending along the outer edge 102e of the dam structure 102 in the direction from the second surface 300b of the substrate 300C to the capping layer 100C. The concave-tapered sidewall 106 also helps to improve the filling and covering ability of the subsequently formed encapsulant layer. As a result, undesired gaps or voids can be avoided at the corners formed by the dam structure 10 and the underlying substrate 300C after the formation of the encapsulant layer.

In some embodiments, the chip packaging body further includes a package substrate 400 and conductive structures 450 (e.g., solder balls, bumps, or conductive posts). More specifically, the package substrate 400 has a first surface 400a (e.g., the lower surface) and a second surface 400b (e.g., an upper surface) opposite each other. Moreover, the second surface 400b of the package substrate 400 adjoins the first surface 300a of the substrate 300C, so that the substrate 300C and the capping layer 100C are successively stacked on the package substrate 400. The conductive structures 450 are formed on and in contact with the first surface 400a of the package substrate 400.

In some embodiments, the chip package further includes one or more bonding wires 410 and an encapsulant layer 420. The bonding wires 410 respectively connect the corresponding conductive pads 305 on the second surface 300b of the substrate 300C with the corresponding conductive pads 401 on the second surface 400b of the package substrate 400. In some embodiments, the conductive structures 450 are electrically connected to the substrate 300C via the bonding wires 410 and the interconnect structures 403 formed in the package substrate 400.

In some embodiments, the encapsulant layer 420 is formed over the second surface 400b of the package substrate 400 and surrounds the substrate 300C, the dam structure 102, and the capping layer 100C. The second surface 100b of the capping layer 100C and the overlying optical film 105 are exposed from the encapsulant layer 420. In some embodiments, the bonding wires 410 are formed in the encapsulant layer 420. Moreover, the encapsulant layer 420 is in direct contact with the stepped sidewall 320 of the substrate 300C and the concave-tapered sidewall 106S of the glue overflow layer 106a (which is formed of the overflowed adhesive layer 106), the outer edge 102e of the dam structure 102, and the edge 100e of the capping layer 100C. As a result, the interface between the capping layer 100C and the encapsulant layer 420 and the interface between the encapsulant layer 420 and the upper portion of the dam structure 120 are substantially aligned with each other and extend in the same direction. Moreover, due to the glue overflow layer 106a having the concave-tapered sidewall 106S, the encapsulant layer 420 forms a rounded angle 420R corresponding to and in direct contact with the concave-tapered sidewalls 106S. In some embodiments, a planarization is not performed on the upper surface of the encapsulant layer 420, so that the encapsulant layer 420 has a curved or arched upper surface 420T to form a tapered sidewall 420S adjacent to the capping layer 100C, as shown in FIG. 1A.

Next, referring to FIGS. 2A to 2G, which are cross-sectional views of a method for forming a chip package in accordance with some embodiments of the present disclosure. Elements in 2A to 2G that are the same as those in FIGS. 1A and 1B are labeled with the same reference numbers as in FIGS. 1A and 1B and are not described again for brevity. Referring to FIG. 2A, a transparent substrate 100W and a carrier substrate 200W are provided. In some embodiments, an optical film 105 is attached onto at least one of two surfaces of the transparent substrate 100W opposite each other (e.g., the lower surface and an upper surface of the transparent substrate 100W). For example, the optical film 105 is attached onto the upper surface of the transparent substrate 100W. In some embodiments, the transparent substrate 100W and the carrier substrate 200W are each a glass wafer to facilitate the wafer-level packaging process. In some other embodiments, the transparent substrate 100W and the carrier substrate 200W are transparent substrates made of quartz, a transparent polymer material, or another suitable transparent material.

In some embodiments, the transparent substrate 100W having the optical film 105 is bonded onto the carrier substrate 200W by a tape layer 101, in which the upper surface of the transparent substrate 100W faces the carrier substrate 200W. The transparent substrate 100W includes first regions R1 and a second region R2 surrounding the first region R1. For example, each first region R1 of the transparent substrate 100W corresponds to a chip region of a device substrate (e.g., a device wafer), while the second region R2 of the transparent substrate 100W corresponds to a scribe-line region of the device substrate. To simplify the diagram, only two non-complete (partial) first regions R1 and a second region R2 separating these first regions R1 are depicted herein.

Next, in some embodiments, dam structures 102 are formed on the lower surface of the transparent substrate 100W. As viewed from a top-view perspective, each dam structure 102 extends along the edge of a corresponding first region R1 to surround the corresponding first region R1. Moreover, each dam structure 102 does not extend into the second region R2.

Referring to FIG. 2B, in some embodiments, openings 104 are formed in the transparent substrate 100W and each opening 104 surrounds a corresponding first region R1. More specifically, a first dicing process using a first dicing saw S1 is performed to partially remove each dam structure 102 and the underlying transparent substrate 100W and optical film 105 to form openings 104. These openings 104 surrounding the corresponding first regions R1 expose the tape layer 101. In some other embodiments, the first dicing process is performed by an chemical etching process (e.g., dry etching process, wet etching process, plasma etching process, reactive ion etching process, or another suitable process) or a laser process. After the first dicing process, the sidewall of the opening and the sidewall of the corresponding dam structure 102 are substantially aligned with each other and extend in the same direction. That is, these sidewalls form a straight line.

Referring to FIG. 2C, in some embodiments, a substrate 300W (e.g., a device wafer) is flipped and bonded onto the transparent substrate 100W. More specifically, an adhesive layer 106 is formed on the surface of each dam structure 102. The substrate 300W is then bonded onto the transparent substrate 100W via the adhesive layer 106, and the substrate 300W is separated from the transparent substrate 100W by the dam structure 102. After the substrate 300W is bonded onto the transparent substrate 100W, the adhesive layer 106 overflows to form a glue overflow layer 106a with a concave-tapered sidewall surrounding the lower portion of the corresponding dam structure 102.

In some embodiments, the substrate 300W has chip regions C that corresponds to the first regions R1 of the transparent substrate 100W, and a scribe-line region SL that corresponds to the second region R2 of the transparent substrate 100W. Similarly, to simplify of the diagram, only two non-complete (partial) chip regions C and one scribe-line region SL separating these chip regions C are depicted herein. In some embodiments, each of the chip regions C of the substrate 300W has the same or similar structure as the substrate 300C (shown in FIG. 1A). For example, the structure of each chip region C includes a substrate 300W, an optical component 303 and one or more conductive pads 305 formed on the surface of the substrate 300W, and a sensing region 301 formed in the substrate 300W and adjacent to the optical component 303.

Next, as shown in FIG. 2D, in some embodiments, a thinning process (e.g., an etching process, a milling process, a grinding process, or a polishing process) is performed on the substrate 300W using the carrier substrate 200W as a carrier, to thin the substrate 300W to the desired thickness.

Referring to FIG. 2E, in some embodiments, after the thinning process, a debonding process is performed. For example, the tape layer 101 may be irradiated with light (e.g., UV light) or heat, so that tape layer 101 loses its adhesion. As a result, the tape layer 101, the carrier substrate 200W, and a portion of the transparent substrate 100W can be removed from the structure shown in FIG. 2D. The remaining transparent substrate 100W forms capping layers 100C on the substrate 300W, and exposes the entire scribe-line region SL and portions of the chip regions C.

Referring to FIGS. 2F and 2G, in some embodiments, a second dicing process is performed on the exposed scribe-line region SL, so that the chip regions C are separated from each other. The substrate 300W of each separated chip region C forms stepped sidewalls 320. More specifically, unlike the first dicing process (shown in FIG. 2B), the second dicing process is a multi-step dicing process (e.g., a two-step dicing process). As shown in FIG. 2F, a first step of the second dicing process is performed using a second dicing saw S2 to form an opening 310 corresponding to the scribe-line region SL in the substrate 300W. In some embodiments, the opening 310 is deep enough to penetrate the insulating layer (which includes an interlayer dielectric (ILD) layer, an inter-metal dielectric (IMD) layer, a passivation layer, or a combination thereof) formed on the surface of the substrate 300W. Afterwards, a second step of the second dicing process is performed using a third dicing saw S3 to form an opening 312 corresponding to the opening 310 in the substrate 300W, as shown in FIG. 2G. The opening 310 and the underlying opening 312 penetrate through the substrate 300W, so that the chip regions C are separated, so that each chip region C includes a stack where the substrate 300C, the dam structure 102, and the capping layer 100C are successively stacked. In some embodiments, the first dicing saw S1, the second dicing saw S2, and the third dicing saw S3 have different widths. For example, the width of the first dicing saw S1 is less than the width of the third dicing saw S3, and the width of the third dicing saw S3 is less than the width of the second dicing saw S2. Since the width of the second dicing saw S2 is greater than the width of the third dicing saw S3 (i.e., the width of the opening 310 is greater than the width of the opening 312), the substrate 300W of each the separated chip region C having stepped sidewalls 320 can be formed. Moreover, since the second dicing process is a two-step dicing process, the rotation speed and the feed speed of the second dicing saw S2 can be adjusted, thereby preventing or mitigating the insulating layer formed on the surface of the substrate from being damaged.

In some embodiments, after forming the stack of the substrate 300C, the dam structure 102, and the capping layer 100C, a package substrate 400 (referring to FIG. 1A) having a first surface 400a (e.g., the lower surface) and a second surface 400b (e.g., the upper surface) opposite each other is provided. Afterwards, the second surface 400b of the package substrate 400 adjoins the substrate 300C having stepped sidewalls 320. Next, one or more bonding wires 410 may be formed to electrically connect the package substrate 400 to the substrate 300C.

Afterwards, an encapsulant layer 420 is formed on the package substrate 400 and surrounds the substrate 300C with stepped sidewalls 320, the dam structure 102, and the capping layer 100C. As a result, the bonding wires 410 are formed inside the encapsulant layer 420. The stepped sidewalls 320 of the substrate 300C and the concave-tapered sidewalls 106S of the glue overflow layer 106a are in direct contact with the encapsulant layer 420. In some embodiments, since a planarization is not performed on the upper surface of the encapsulant layer 420, the formed encapsulant layer 420 has a curved or arched upper surface 420T to form a tapered sidewall 420S adjacent to the capping layer 100C, as shown in FIG. 1A.

Next, conductive structures 450 are formed on the first surface 400a of the package substrate 400 and are in contact with the package substrate 400. The conductive structures 450 are electrically connected to the substrate 300C by the bonding wires 410 and the interconnect structure 403 formed in the package substrate 400, as shown in FIG. 1A.

According to the foregoing embodiments, since the capping layer is formed by using a wafer-level package process, the yield of the capping layer can be improved. Moreover, according to the foregoing embodiments, since the outer edge of the dam structure is substantially aligned with the edge of the capping layer, the dam structure can provide stronger mechanical support for the capping layer when the capping layer is stacked over the substrate via the dam structure. In addition, according to the foregoing embodiments, since the substrate has stepped sidewalls and the formed glue overflow layer has concave-tapered sidewalls, it can provide better filling and covering capability for the subsequently formed encapsulant layer, thereby increasing reliability of the chip package.

While the invention has been disclosed in terms of the preferred embodiments, it is not limited. The various embodiments may be modified and combined by those skilled in the art without departing from the concept and scope of the invention.

What is claimed is:

1. A chip package, comprising:
a substrate having a stepped sidewall and a first surface and a second surface opposite each other and adjoining the stepped sidewall;
a capping layer having a first surface and a second surface opposite each other, wherein the first surface of the capping layer faces the second surface of the substrate;
a dam structure bonding the capping layer to the substrate and surrounding a sensing region in the substrate; and
an adhesive layer surrounding the dam structure, wherein the adhesive layer has a concave-tapered sidewall extending along an outer edge of the dam structure in a direction from the second surface of the substrate to the capping layer.

2. The chip package as claimed in claim 1, wherein the outer edge of the dam structure is substantially aligned with an edge of the dam structure.

3. The chip package as claimed in claim 1, further comprising:
a package substrate having a first surface and a second surface opposite each other, wherein the second surface of the package substrate adjoins the first surface of the substrate; and
an encapsulant layer formed on that second surface of the package substrate and surrounding the substrate, the dam structure and the capping layer, wherein the second surface of the capping layer is exposed from the encapsulant layer.

4. The chip package as claimed in claim 3, wherein the encapsulant layer is in direct contact with the stepped sidewall of the substrate and the concave-tapered sidewall of the adhesive layer.

5. The chip package as claimed in claim 3, wherein the encapsulant layer has a curved upper surface to form a tapered sidewall adjacent to the capping layer.

6. The chip package as claimed in claim 3, further comprising a bonding wire connecting a conductive pad disposed on the second surface of the substrate to a conductive pad disposed on the second surface of the package substrate.

7. The chip package as claimed in claim 3, further comprising a plurality of conductive structures formed on the first surface of the package substrate.

8. The chip package as claimed in claim 1, further comprising an optical component formed on the second surface of the substrate and corresponding to the sensing region.

9. The chip package as claimed in claim 1, further comprising an optical film formed on the first or second surface of the capping layer.

10. A chip package, comprising:
a substrate and a capping layer, successively stacked on a package substrate;
a dam structure sandwiched between the substrate and the capping layer and surrounding a sensing region in the substrate;
an encapsulant layer formed on the package substrate and surrounding the substrate, the dam structure and the capping layer; and
an adhesive layer formed between a lower portion of the dam structure and the encapsulant layer;
wherein a bottom width of the substrate is greater than a top width of the substrate;
wherein a first interface between the capping layer and the encapsulant layer and a second interface between the encapsulant layer and an upper portion of the dam structure are substantially aligned with each other and extend in the same direction; and
wherein the encapsulant layer has a rounded angle in direct contact with the adhesive layer.

11. The chip package as claimed in claim 10, wherein the substrate has a stepped sidewall that is in direct contact with the encapsulant layer.

12. The chip package as claimed in claim 10, wherein the encapsulant layer has a curved upper surface to form a tapered sidewall adjacent to the capping layer.

13. The chip package as claimed in claim 10, further comprising:
an optical component formed over the substrate and corresponding to the sensing region; and
an optical film formed over one of two opposite surfaces of the capping layer.

14. The chip package as claimed in claim 13, wherein the optical film includes an infrared cut filter, an antireflection layer, or a combination thereof.

15. The chip package as claimed in claim 10, further comprising:
a bonding wire formed in the encapsulant layer and electrically connecting the substrate to the package substrate; and
a plurality of conductive structures in contact with the package substrate and electrically connected to the substrate via the bonding wire.

16. A method for forming a chip package, comprising:
bonding a transparent substrate to a carrier substrate via a tape layer, wherein the transparent substrate has a first region and a second region surrounding the first region;
forming a dam structure on the transparent substrate, wherein the dam structure extends along an edge of the first region to surround the first region;
performing a first dicing process to partially remove the dam structure and form an opening in the transparent substrate, wherein the opening surrounds the first region and exposes the tape layer;
bonding a substrate to the transparent substrate, wherein the substrate has a chip region corresponding to the first region and a scribe-line region corresponding to the second region;
performing a debonding process to remove the tape layer, the carrier substrate, and a portion of the transparent substrate, so that a remaining transparent substrate forms a capping layer over the substrate and exposes the scribe-line region; and
performing a second dicing process on the exposed scribe-line region, so that the substrate of the chip region forms a stepped sidewall.

17. The method as claimed in claim 16, wherein a sidewall of the opening and a sidewall of the dam structure are substantially aligned with each other and extend in a same direction.

18. The method as claimed in claim 16, wherein the substrate is bonded to the transparent substrate via an adhesive layer, wherein after the substrate is bonded to the transparent substrate, the adhesive layer overflows to form a glue overflow layer having a concave-tapered sidewall surrounding a lower portion of the dam structure.

19. The method as claimed in claim 18, further comprising:
bonding a package substrate to the substrate having the stepped sidewall;
forming a bonding wire to electrically connect the package substrate to the substrate having such stepped sidewalls; and
forming an adhesive layer on the encapsulated layer and surrounding the substrate having the stepped sidewall, the dam structure, and the capping layer;
wherein the encapsulant layer is in direct contact with the stepped sidewall and the concave-tapered sidewall.

20. The method as claimed in claim 19, wherein the encapsulant layer has a curved upper surface to form a tapered sidewall adjacent to the capping layer.

21. The method as claimed in claim 19, further comprising forming a plurality of conductive structures in contact with the package substrate, and wherein the substrate having the stepped sidewalls is electrically connected to the plurality of conductive structures by the bonding wire.

22. The method as claimed in claim 16, wherein the first dicing process is performed using a first dicing saw, and the second dicing process is performed successively using a second dicing saw and a third dicing saw.

23. The method as claimed in claim 22, wherein the first dicing saw, the second dicing saw and the third dicing saw have different widths.

24. The method as claimed in claim 16, further comprising forming an optical film on one of the two opposite surfaces of the transparent substrate.

25. The method as claimed in claim 24, wherein the optical film comprises an infrared cut filter, anti-reflection layer, or a combination thereof.

26. The method as claimed in claim 16, further comprising performing a thinning process on the substrate prior to the debonding process.
